(19) United States
(12) Patent Application Publication
(10) Pub. No.: US 2023/0420246 A1
(43) Pub. Date: Dec. 28, 2023

(54) SPUTTER TARGETS AND SOURCES FOR SELF-DOPED SOURCE AND DRAIN CONTACTS

(71) Applicant: Intel Corporation, Santa Clara, CA (US)

(72) Inventors: Ilya V. Karpov, Portland, OR (US); Aaron A. Budrevich, Portland, OR (US); Gilbert Dewey, Beaverton, OR (US); Matthew V. Metz, Portland, OR (US); Jack T. Kavalieros, Portland, OR (US); Dan S. Lavric, Portland, OR (US)

(73) Assignee: Intel Corporation, Santa Clara, CA (US)

(21) Appl. No.: 17/847,625

(22) Filed: Jun. 23, 2022

(51) Int. Cl. H01L 21/02; H01L 21/24; H01L 29/66; H01L 29/78

(52) U.S. Cl. CPC H01L 21/02266; H01L 29/785; H01L 29/66803; H01L 21/24

(57) ABSTRACT

An integrated circuit structure includes a source or drain region, and a contact coupled to the source or drain region. A region including metals and semiconductor materials is between the source or drain region and the contact. A first dopant is within the source or drain region, and a second dopants is within the region. In one example, the first dopant is elementally different from the second dopant. In another example, the first dopant is elementally same as the second dopant, wherein a concentration of the first dopant within a section of the source or drain region is within 20% of a concentration of the second dopant within the region, and wherein the section of the source or drain region is at a distance of at most 5 nanometers (nm) from the region.

### BACKGROUND

Integrated circuitry continues to scale to smaller feature dimensions and higher transistor densities. As a result, a gate pitch, as well as a pitch for source and drain contacts, continue to reduce. This reduces contact area between a source or drain region and a corresponding source or drain contact, which leads to increased contact resistance and which may negatively impacting transistor performance.

### BRIEF DESCRIPTION OF THE DRAWINGS

FIG. 1A illustrates a cross-sectional view of an example integrated circuit device, where the device comprises (i) a source region, a corresponding source contact, and a first region comprising metal and semiconductor material between the source region and the source contact, (ii) a drain region, a corresponding drain contact, and a second region comprising metal and semiconductor material between the drain region and the drain contact, wherein a first dopant is within the first region and a second dopant is within at least a section of the source region, and wherein the first dopant and the second dopant are elementally different, in accordance with an embodiment of the present disclosure.

FIG. 1B illustrates a graph depicting doping concentrations within the source region of FIG. 1A, and within the first region comprising metal and semiconductor material between the source region and the source contact of FIG. 1A, in accordance with an embodiment of the present disclosure.

FIG. 1C illustrates a cross-sectional view of an example FinFET integrated circuit device, where the device comprises (i) a source region, a corresponding source contact, and a first region comprising metal and semiconductor material between the source region and the source contact, (ii) a drain region, a corresponding drain contact, and a second region comprising metal and semiconductor material between the drain region and the drain contact, wherein a first dopant is within the first region and a second dopant is within at least a section of the source region, and wherein the first dopant and the second dopant are elementally different, in accordance with an embodiment of the present disclosure.

FIG. 2A illustrates a cross-sectional view of an example integrated circuit device, where the device comprises (i) a source region, a corresponding source contact, and a first region comprising metal and semiconductor material between the source region and the source contact, (ii) a drain region, a corresponding drain contact, and a second region comprising metal and semiconductor material between the drain region and the drain contact, wherein a concentration of a dopant within the first region is within 20% of a concentration of the dopant within a section of the source region, where the section of the source region is within a threshold distance from the first region, in accordance with an embodiment of the present disclosure.

FIG. 2B illustrates a graph depicting doping concentrations within the source region of FIG. 2A, and within the first region comprising metal and semiconductor material between the source region and the source contact of FIG. 2A, in accordance with an embodiment of the present disclosure.

FIG. 3 illustrates a flowchart depicting a method of forming any of the example integrated circuit device of FIG. 1A or 1B, in accordance with an embodiment of the present disclosure.

FIGS. 4A, 4B, 4C, 4D, 4E, and 4F collectively illustrate cross-sectional views of an example integrated circuit device semiconductor structure (e.g., the integrated circuit device of FIG. 1A or 2A) in various stages of processing, in accordance with an embodiment of the present disclosure.

FIG. 5 illustrates a computing system implemented with integrated circuit structures and/or transistor devices formed using the techniques disclosed herein, in accordance with an embodiment of the present disclosure.

These and other features of the present embodiments will be understood better by reading the following detailed description, taken together with the figures herein described. In the drawings, each identical or nearly identical component that is illustrated in various figures may be represented by a like numeral. For purposes of clarity, not every component may be labeled in every drawing. Furthermore, as will be appreciated, the figures are not necessarily drawn to scale or intended to limit the described embodiments to the specific configurations shown. For instance, while some figures generally indicate straight lines, right angles, and smooth surfaces, an actual implementation of the disclosed techniques may have less than perfect straight lines and right angles (e.g., curved or tapered sidewalls and round corners), and some features may have surface topography or otherwise be non-smooth, given real-world limitations of fabrication processes. Further still, some of the features in the drawings may include a patterned and/or shaded fill, which is merely provided to assist in visually identifying the different features. In short, the figures are provided merely to show example structures.

### DETAILED DESCRIPTION

Integrated circuit structures are disclosed, which includes transistor devices having source and drain regions, and corresponding source and drain contacts. One or more regions of silicide, germanide, and/or germanosilicide are between a source or drain region and a corresponding contact. In an example, one or more metals are initially deposited over the source or drain region, and during an annealing process, the one or more metals combine or otherwise react with the semiconductor material of the source or drain region, to form the silicide, germanide, and/or germanosilicide. Subsequently, the contact is formed (e.g., by deposition of contact fill metal), such that the silicide, germanide, and/or germanosilicide separate the contact from the source or drain region. In one embodiment, the one or more metals for the silicide, germanide, and/or germanosilicide are pre-doped with a dopant, and as a result, the silicide, germanide, and/or germanosilicide that results from the annealing process also includes the dopant. As the metal from which the silicide, germanide, and/or germanosilicide is formed already has the dopant (e.g., at least in part saturated with the dopant), dopant from the source or drain region may not substantially diffuse from the source or drain region into the silicide, germanide, and/or germanosilicide region, during the annealing process. This maintains satisfactory concentration of dopant within the source or drain region, which in turn facilitates in maintaining satisfactory contact resistance between the source or drain region and subsequently formed contact. As will be described in further detail below, the dopant pre-doped within the metal that reacts with the semiconductor material of the source and drain regions may be same as the dopant of the source or drain region or may be different, and in both scenarios, depletion of dopant concentration in the source or drain region (e.g., due to diffusion of dopant from the source or drain region to the silicide, germanide, and/or germanosilicide) is prevented or at least reduced.

In one embodiment, an integrated circuit structure comprises a source or drain region, and a contact coupled to the source or drain region. A region comprising one or more metals and one or more semiconductor materials is between at least a section of the source or drain region and the contact. In an example, the region comprises one or more of silicide, germanide, and/or germanosilicide of the one or more metals. In an example, a first dopant is within the source or drain region, and a second dopant is within the region. In an example, the first dopant is elementally different from the second dopant. In an example, the first dopant is also within the region, where a concentration of the first dopant within the region is less than a concentration of the first dopant within the source or drain region. In an example, the second dopant is also within the source or drain region, where a concentration of the second dopant within the source or drain region is less than a concentration of the second dopant within the region. In an example, each of the first and second types of dopant comprises a same p-type dopant. In another example, the first dopant comprises a p-type dopant, and the second dopant comprises neither a p-type nor an n-type dopant. In an example, the first dopant comprises boron, and the second dopant comprises one or more of gallium, indium, aluminum, or carbon. In an example, each of the first and second dopants comprises a same n-type dopant. In another example, the first dopant comprises an n-type dopant, and the second dopant comprises neither a p-type nor an n-type dopant. In an example, the first dopant comprises phosphorous, and the second dopant comprises one or more of arsenic, antimony, bismuth, tellurium, or carbon. In an example, the one or more metals comprise one or more of titanium, gadolinium, erbium, scandium, molybdenum, niobium, nickel, cobalt, tungsten, or iridium.

In another embodiment, an integrated circuit structure comprises a source or drain region, a contact coupled to the source or drain region, and a region comprising one or more of silicide, germanide, and/or germanosilicide. The region may be between a section of the source or drain region and the contact. In an example, a section of the source or drain region is within 5 nanometers (nm) of the region. In an example, a dopant is within the region and within the source or drain region, wherein a concentration of the dopant within the region is within 20% of a concentration of the dopant within the section of the source or drain region. In an example, the integrated circuit structure is a p-channel metal-oxide-semiconductor (PMOS) device, and the dopant comprises one or more of boron, gallium, indium, or aluminum. In another example, the integrated circuit structure is a n-channel metal-oxide-semiconductor (NMOS) device, and the dopant comprises one or more of phosphorous, arsenic, antimony, bismuth, or tellurium.

In yet another embodiment, a method for forming a region comprising silicide, germanide, and/or germanosilicide adjacent to a source or drain region is disclosed. The method comprises forming the source or drain region, the source or drain region covered by dielectric material, and forming a recess within the dielectric material. The recess lands on the source or drain region. In an example, the method further includes depositing metal within a bottom section of the recess and adjacent to the source or drain region, wherein the deposited metal is doped with a dopant. In an example, the method further includes processing (e.g., annealing) the metal and the source or drain region, to form the silicide, germanide, and/or germanosilicide adjacent to the source or drain region. In an example, the method includes forming a contact, such that the silicide, germanide, and/or germanosilicide is between the source or drain region and the contact. In an example, the dopant within the metal is a first dopant, and the method further comprises prior to forming the recess, doping at least a section of the source or drain region with a second dopant. In an example, the first dopant is elementally different from the second dopant; while in another example the first dopant is elementally same as the second dopant. In an example, the source or drain region is a p-type source or drain region, the second dopant is a p-type dopant, and the first dopant is either (i) a p-type dopant, or (ii) neither a p-type dopant nor an n-type dopant. In an example, the source or drain region is a n-type source or drain region, the second dopant is an n-type dopant, and the first dopant is either (i) an n-type dopant, or (ii) neither a p-type dopant nor an n-type dopant. Numerous configurations and variations will be apparent in light of this disclosure.

### General Overview

As previously discussed herein, with scaling of integrated circuitry, contact area between a source or drain region and a corresponding source or drain contact reduces, thereby correspondingly increasing the contact resistance. In some examples, to reduce the contact resistance, a silicide (and/or germanide and/or germanosilicide) is formed between the source or drain region and the corresponding contact. In an example, the source or drain region is doped with one or more appropriate types of dopants (e.g., a p-type dopant for PMOS, or an n-type dopant for NMOS), and the doping of the source or drain region further contributes to reducing contact resistance between the source or drain region and the contact. However, when forming the silicide (and/or germanide and/or germanosilicide), a dopant from the source or drain region may diffuse to the silicide (and/or germanide and/or germanosilicide), thereby depleting or reducing a dopant concentration within the source or drain region, which adversely contributes to increasing the contact resistance.

Accordingly, techniques are provided herein to form an IC that includes transistor devices comprising source or drain regions and corresponding contacts, where metals for the silicide (and/or germanide and/or germanosilicide) are pre-doped with one or more dopants, which prevent or at least reduces diffusion of dopant from the source or drain region to the silicide (and/or germanide and/or germanosilicide). This in turn facilitates in maintaining satisfactory level of dopant within the source or drain region, which in turn facilitates in maintaining satisfactory contact resistance between the source or drain region and the corresponding contact.

Unless mentioned otherwise or unless referring specifically to silicide, any discussion with respect to silicide may also apply to germanide and/or germanosilicide. Thus, for example, discussion about a silicide region between a source or drain region and a corresponding contact may also apply to a germanide region or a germanosilicide region between the source or drain region and the corresponding contact. Also note that formation of silicide, germanide, and/or germanosilicide may depend on semiconductor materials used for the source or drain regions. For example, in a PMOS device, the source and drain regions may comprise SiGe doped with an appropriate p-type dopant, and hence, silicide, germanide, and/or germanosilicide may be formed adjacent to the source or drain regions of the PMOS device. In another example, in an NMOS device, the source and drain regions may comprise Si, and hence, silicide (but not germanide or germanosilicide) may be formed adjacent to the source or drain regions of the NMOS device.

Referring again to the above discussed example of using pre-doped metal for the silicide (and/or germanide and/or germanosilicide) region, in an example, the metal for the silicide (and/or germanide and/or germanosilicide) is pre-doped with a first dopant. That is, the metal deposited within the source or drain trench, for formation of the silicide region, comprises the first dopant. For example, the metal has about 0.5 to 25% by atomic weight of the first dopant doped therewith. The metal and the source or drain region are annealed at high temperature, during which the pre-doped metal combines with the semiconductor material (e.g., silicon or SiGe), to form the silicide, germanide, and/or germanosilicide region(s). The source or drain contact is then formed, such that the silicide (and/or germanide and/or germanosilicide) region is between the source or drain region and the corresponding contact.

While the metal for the silicide (and/or germanide and/or germanosilicide) region is pre-doped with the first dopant, the source or drain region is pre-doped (e.g., doped prior to metal deposition for formation of the silicide region) with a second dopant, which may be elementally same as, or different from, the first dopant, as will be discussed herein in turn.

As discussed, after the metal is deposited, during an anneal process or another appropriate high-temperature process, the metal combines with the semiconductor material of the source or drain region, to form the silicide (and/or germanide and/or germanosilicide) region. As the metal for the silicide (and/or germanide and/or germanosilicide) region is pre-doped with the first dopant, the resultant silicide (and/or germanide and/or germanosilicide) region also includes the first dopant. Thus, the silicide (and/or germanide and/or germanosilicide) region is now somewhat saturated with the first dopant, and cannot accept substantial number of atoms of the second dopant from the source or drain region. Put differently, substantial diffusion of the second dopant from the source or drain region to the silicide (and/or germanide and/or germanosilicide) region is blocked or at least reduced, as the silicide (and/or germanide and/or germanosilicide) region already includes the first dopant. Note that some atoms of the second dopant may still diffuse from the source or drain region to the silicide (and/or germanide and/or germanosilicide) region, but a number of atoms of such diffused second dopant is much less than the previously discussed example (e.g., where the deposited metal for formation of the silicide region was undoped) in which substantial amount (e.g., a relatively larger number of atoms) of dopant diffuse from the source or drain region to the silicide (or germanide and/or germanosilicide) region. Accordingly, the source or drain region does not have a substantial reduction in the second dopant (e.g., due to substantially less atoms of the second dopant diffusing to the silicide (and/or germanide and/or germanosilicide) region). Hence, satisfactory level of concentration of the second dopant is maintained within the source or drain region, and as a result, satisfactory level of contact resistance between the source or drain region and the contact is achieved. Note that some atoms of the first dopant may also migrate from the silicide (and/or germanide and/or germanosilicide) region to the source or drain region, which may, in some examples, advantageously further increase dopant concentration of the source or drain regions.

In an example, assuming that the device is a PMOS device, the second of dopant within the source or drain region is a p-type dopant. The second dopant pre-doped within the metals of the silicide (and/or germanide and/or germanosilicide) region may either be p-type, or may be neither p-type nor n-type (such as carbon). Irrespective of whether the second dopant is one of (i) a p-type or (ii) neither a p-type nor an n-type, presence of the second dopant within the silicide (and/or germanide and/or germanosilicide) region deters or reduces diffusion of the first dopant from the source or drain region to the silicide (and/or germanide and/or germanosilicide) region, thereby maintaining satisfactory level of concentration of the second dopant within the source or drain region.

In an example, assuming that the device is a NMOS device, the second dopant within the source or drain region is a n-type dopant. The second dopant pre-doped within the metals of the silicide (and/or germanide and/or germanosilicide) region may either be an n-type, or may be neither an n-type nor a p-type (such as carbon). Irrespective of whether the second dopant is one of (i) n-type or (ii) neither p-type nor n-type, presence of the second dopant within the silicide (and/or germanide and/or germanosilicide) region deters or reduces diffusion of the first dopant from the source or drain region to the silicide (and/or germanide and/or germanosilicide) region, thereby maintaining satisfactory level of concentration of the second dopant within the source or drain region.

In a first set of examples, assume that the first dopant and the second dopant are elementally different. For example, for an NMOS device, the second dopant can be an n-type dopant such as phosphorous, and the first dopant may comprise other one or more n-type of dopants such as arsenic, antimony, bismuth, tellurium (but not phosphorous), or a dopant that is neither p or n types (such as carbon). In another example, for a PMOS device, the second dopant can be a p-type dopant such as boron, and the first dopant may comprise other one or more p-type of dopants such as gallium, indium, aluminum (but not boron), or a dopant that is neither a p or an n type (such as carbon). Thus, in these examples, the first dopant is primarily within the silicide (and/or germanide and/or germanosilicide) region, and the second dopant is primarily within the source or drain region. For example, a concentration of the first dopant within the silicide (and/or germanide and/or germanosilicide) region is at least 20%, or 15%. or 10%, or 5% higher than a concentration of the first dopant within the source or drain region. Similarly, a concentration of the second dopant within the source or drain region is at least 20%, or 15%. or 10%, or 5% higher than a concentration of the second dopant within the silicide (and/or germanide and/or germanosilicide) region.

In a second set of examples, assume that the first dopant and the second dopant are elementally the same. For example, for an NMOS device, the first dopant and the second dopant can be a same n-type dopant such as phosphorous. In another example, for a PMOS device, the first dopant and the second dopant can be a same p-type dopant such as boron. In such an example, a concentration of the dopant within the silicide (and/or germanide and/or germanosilicide) region is substantially similar (e.g., within 25%, or 20%, or 15%, or 10%, or 5%) to a concentration of the dopant within at least a section of the source or drain region, where the section of the source or drain region is proximal to the silicide (and/or germanide and/or germanosilicide) region. For example, the section of the source or drain region is within a threshold distance d1 from the silicide (and/or germanide and/or germanosilicide) region, where the distance d1 is in the range of 2-15 nanometers (nm), or in the subrange of 2-12 nm, 2-10 nm, 2-8 nm, 2-5 nm, 5-15 nm, or 5-10 nm. Thus, there is sufficient dopant within the source or drain region and adjacent to the silicide (and/or germanide and/or germanosilicide) region and the source or drain contact, thereby achieving a satisfactory level of source or drain contact resistance.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are “elementally different,” then one of the material has an element that is not in the other material.

In some embodiments, a plurality of channel layers of compositionally different channel materials or geometries may be formed on different areas of the substrate, such as for CMOS applications, for example. For instance, a first channel material layer may be formed on a first area of a silicon base to be used for one or more p-channel transistor devices (e.g., one or more PMOS devices) and a second channel material layer may be formed on a second area of the silicon base to be used for one or more n-channel transistor devices (e.g., one or more NMOS devices). As previously described, by selecting the substrate to have the desired material characteristics (e.g., the desired semiconductor material, the desired dopant concentration, and desired dopant type) the substrate can be used to grow multiple different channel layers.

Note that the use of “source/drain” herein is simply intended to refer to a source region or a drain region or both a source region and a drain region. To this end, the forward slash (“/”) as used herein means “and/or” unless otherwise specified, and is not intended to implicate any particular structural limitation or arrangement with respect to source and drain regions, or any other materials or features that are listed herein in conjunction with a forward slash.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some embodiments, such tools may indicate a transistor device having (i) a source or drain region, (ii) a corresponding source or drain contact, and (iii) a region comprising silicide, germanide, and/or germanosilicide between the source or drain region and the source or drain contact, wherein a concentration of a first dopant within the source or drain region is higher than that within the region, wherein a concentration of a second dopant within the region is higher than that within the source or drain region, and where the first dopant is elementally different from the second dopant. Furthermore, such tools may also be used to indicate a transistor device having (i) a source or drain region, (ii) a corresponding source or drain contact, and (iii) a region comprising silicide, germanide, and/or germanosilicide between the source or drain region and the source or drain contact, wherein a concentration of a dopant within a section of the source or drain region is within 20% (or within 15%, or 10%, or 5%) of a concentration of the dopant within the region, wherein the section of the source or drain region is within a threshold distance d1 from the region, and where the distance d1 is in the range of 2-15 nanometers (nm), or in the subrange of 2-12 nm, 2-10 nm, 2-8 nm, 2-5 nm, nm, or 5-10 nm. Numerous configurations and variations will be apparent in light of this disclosure.

### Architecture and Methodology

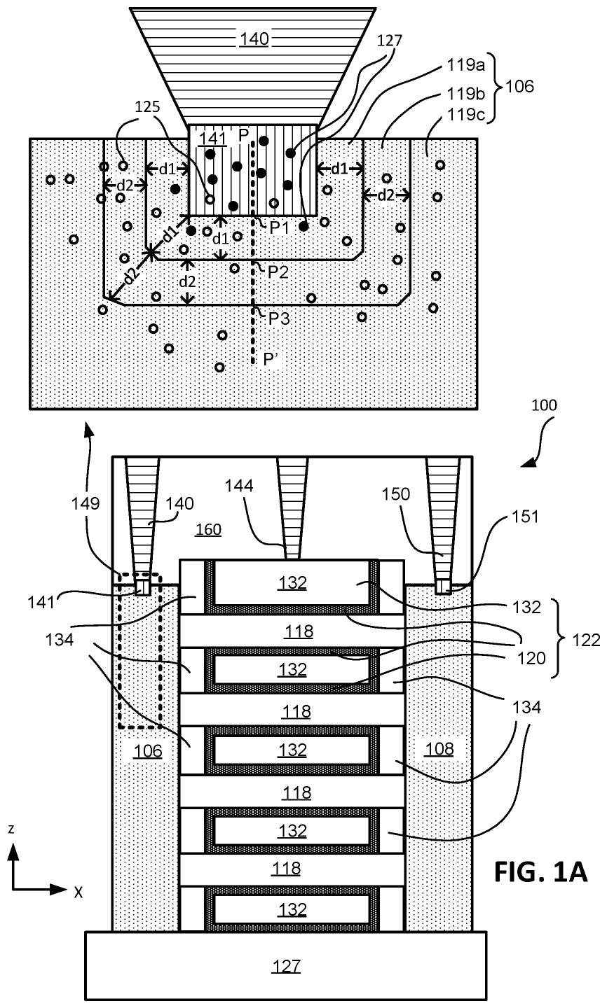

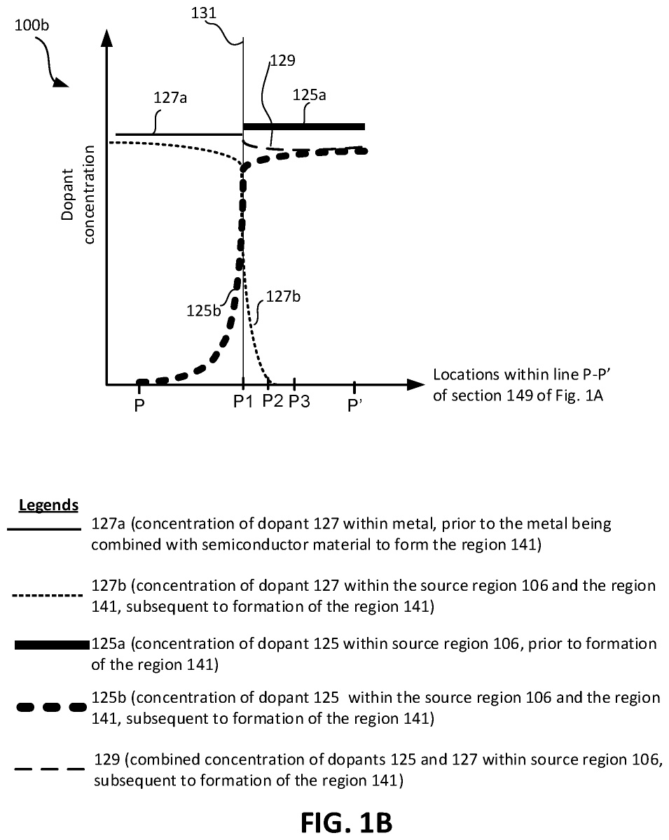

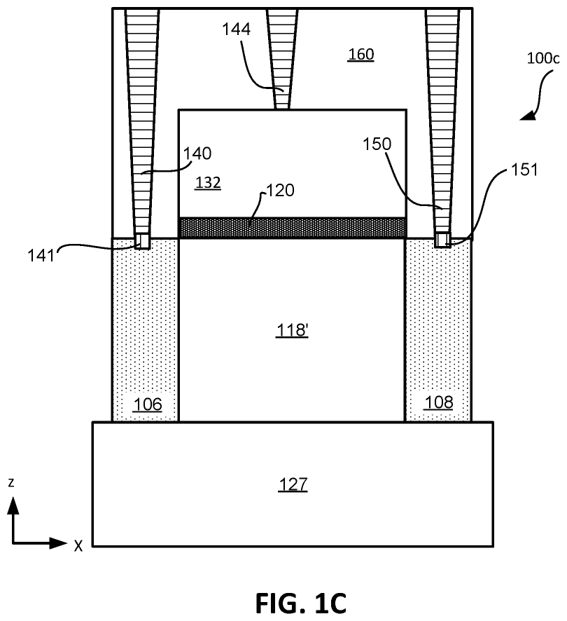

FIG. 1A illustrates a cross-sectional view of an example integrated circuit device 100 (also referred to herein as “device 100”), where the device 100 comprises (i) a source region 106, a corresponding source contact 140, and a first region 141 comprising metal and semiconductor material (e.g., silicon and/or germanium) between the source region 106 and the source contact 140, (ii) a drain region 108, a corresponding drain contact 150, and a second region 151 comprising metal and semiconductor material (e.g., silicon and/or germanium) between the drain region 108 and the drain contact 150, wherein a first dopant 127 is within the first region 141 and a second dopant 125 is within at least a section 119a of the source region 106, and wherein the first dopant 127 and the second dopant 125 are elementally different, in accordance with an embodiment of the present disclosure.

In FIG. 1A, the semiconductor bodies included in the channel region of the device 100 can vary in form, but in this example embodiment are in the form of nanoribbons 118. In particular, the channel region of the device 100 in this example case include a set of four nanoribbons 118. Other examples may include fewer nanoribbons (e.g., one or two), or more nanoribbons (e.g., five or six). Still other embodiments may include other channel configurations, such as one or more nanowires, nanosheets, or a fin (e.g., such as shown FIG. 1C) or other semiconductor body, including both planar and nonplanar topologies. To this end, the present disclosure is not intended to be limited to any particular channel configuration or topology; rather the techniques provided herein can be used in any transistor architecture that uses silicide, germanide, and/or germanosilicide adjacent to its source or drain regions.

Note that in an example, the location of the source and drain regions in the device 100 may be interchanged, and the source and drain regions are also generically referred to herein as a source or drain region. Thus, a source or drain region may refer to either of a source region or a drain region. The source and drain regions will be discussed in further details herein in turn. Some of the discussions herein focus on the source region, and such discussion may also be applicable to the drain region as well.

In the example of FIG. 1A, a gate structure 122 wraps around individual nanoribbons 118. Gate spacers 134 isolates the gate structure 122 from contacting the source region 106 and the drain region 106. In other embodiments, there may be other insulator layers (e.g., interlayer dielectric) that prevent such contact, whether in addition to the gate spaces 134, or in place of the gate spacers 134. In one embodiment, gate spacers 134 may include a dielectric material, such as silicon nitride. In an example, a conductive gate contact 144 provides contacts to the gate structure 122 of the device 100.

The gate structure 122 can be formed via gate-first or gate-last processing, and may include any number of suitable gate materials and configurations. In an embodiment, the gate structure 122 includes a corresponding gate electrode 132 and gate dielectric 120 between the gate electrode 132 and the corresponding nanoribbons 118. In one example the gate spacers 134 may be considered to be part of the gate structure 122, whereas in another example the gate spacers 134 may be considered external to the gate structure 122.

The gate structure 122 of the device 100 comprises the corresponding gate electrode 127 and corresponding dielectric material 120. The gate dielectric material 120 warps around middle section of individual nanoribbons 118 (note that end sections of individual nanoribbons 118 are wrapped around by the gate spacers 134). The gate dielectric material 120 is between individual nanoribbons 118 and the gate electrode 132, as illustrated. In an example, due to conformal deposition of the gate dielectric material 120, the gate dielectric material 120 may also be on inner sidewalls of the gate spacer 134, as illustrated.

The gate dielectric 120 may include a single material layer or multiple stacked material layers. The gate dielectric may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 120 is lanthanum. In some embodiments, the gate dielectric 120 can be annealed to improve its quality when high-k dielectric material is used. In some embodiments, the gate dielectric 120 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer.

In an example, the gate electrode 132 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example.

In one embodiment, one or more work function materials (not illustrated in FIG. 1) may be included around the nanoribbons 132. Note that work function materials are called out separately, but may be considered to be part of the gate electrode 132. In this manner, a gate electrode may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons 118. In still other embodiments, there may be insufficient room for any gate fill material, after deposition of work function material (a given gate electrode may be all work function material and no fill material). Numerous gate structure configurations can be used along with the techniques provided herein, and the present disclosure is not intended to be limited to any particular such configurations.

The semiconductor bodies 118, which in this case are nanoribbons, can be any number of semiconductor materials as well, such as group IV material (e.g., silicon, germanium, or SiGe) or group III-V materials (e.g., indium gallium arsenide). In other embodiments, the semiconductor bodies 118 may be fins on which the corresponding gate structures are formed to provide double-gate or tri-gate configurations (as opposed to gate-all-around configurations with nanoribbons or wires). The semiconductor bodies 118 may be lightly doped, or undoped, and may be shaped or sculpted during the gate formation process, according to some embodiments. In some cases, semiconductor bodies 118 may be a multilayer structure, such as a SiGe body cladded with germanium, or a silicon body cladded with SiGe. Any number of channel configurations can be used.

The source region 106 and the drain region 108 can be any suitable semiconductor material and may include any dopant scheme. In an example, source and drain regions 106, 108 can be PMOS source and drain regions that include, for example, group IV semiconductor materials such as silicon, germanium, SiGe, germanium tin (GeSn), SiGe alloyed with carbon (SiGe:C). Example p-type dopants include boron, gallium, indium, and aluminum. In another example, source and drain regions 106, 108 can be NMOS source and drain regions that include, for example, silicon or group III-V semiconductor materials such as two or more of indium, aluminum, arsenic, phosphorus, gallium, and antimony, with some example compounds including but not limited to indium aluminum arsenide, indium arsenide phosphide, indium gallium arsenide, indium gallium arsenide phosphide, gallium antimonide, gallium aluminum antimonide, indium gallium antimonide, or indium gallium phosphide antimonide. In one specific embodiment, PMOS source and drain regions are boron-doped SiGe, and NMOS source and drain regions are phosphorus-doped silicon. In a more general sense, the source and drain regions can be any semiconductor material suitable for a given application. In some cases, the epi source and drain regions may include a multilayer structure, such as a germanium cap on a SiGe body, or a germanium body and a carbon-containing SiGe spacer or liner between the corresponding channel region and that germanium body. In any such cases, a portion of the epi source and drain regions may have a component that is graded in concentration, such as a graded germanium concentration to facilitate lattice matching, or a graded dopant concentration to facilitate low contact resistance. Any number of source and drain configurations can be used as will be appreciated, and the present disclosure is not intended to be limited to any particular such configurations.

As illustrated in FIG. 1A, a source contact 140 is coupled to the source region 106, and a drain contact 150 is coupled to the drain region 108. In an example, the source contact 140 and the drain contact 150 comprise appropriate conductive material, such as one or more metals or an alloy thereof. In an example, the source or drain contacts may include conductive material that are similar to (or different from) the conductive material of the gate electrode 132. In an example, the source contact 140 may extend within the source region 106, and the drain contact 150 may extend within the drain region 108. Fill materials for the source contact 140 and the drain contact 150 include conductive material, such as one or more metal or alloy(s) thereof. Examples of conductive materials included in the fill materials for the source contact 140 and the drain contact 150 include aluminum, tungsten, titanium, tantalum, copper, cobalt, molybdenum, titanium nitride, or tantalum nitride, for example.

FIG. 1A illustrates an expanded view of a section 149 of the device 100, where the section 149 includes parts of the source region 106, the source contact 140, and the conductive region 141 between the source contact 140 and the source region 106. Various discussion herein below focuses on the source region 106, the source contact 140, and the conductive region 141, and such discussion also applies to the drain region 106, the drain contact 140, and the conductive region 151 between the drain region 106 and the drain contact 140. In an example, locations of the source region 106, the source contact 140, and the conductive region 141 can be respectively interchanged with the drain region 108, the drain contact 150, and the conductive region 151.

As illustrated, in an example, the conductive region 141 is between the source contact 140 and the source region 106. In an example, the region 141 is considered to be a part of the source region 106, and the region 151 is considered to be a part of the drain region 108, although in another examples the regions 141 and 151 are considered to be different from the corresponding source or drain regions. Similarly, in an example, the region 141 is considered to be a part of the source contact 140, and the region 151 is considered to be a part of the drain contact 150, although in another examples the regions 141 and 151 are considered to be different from the corresponding source or drain contacts. In an example, the conductive regions 141, 151 are representative of one or more silicide region(s), germanide region(s), and/or germanosilicide region(s) between the conductive source or drain metal contact and the adjacent source or drain region. In an example, the regions 141, 151 reduce contact resistance of the source and drain contacts.

In an example, the source and drain regions 106, 108 comprise semiconductor materials, such as Si, Ge, and/or SiGe. In an example, the device 100 is a PMOS device, while in another example the device 100 is an NPMOS device. In an example, if the device 100 is a PMOS device, the PMOS source and drain regions may comprise SiGe doped with an appropriate p-type dopant. On the other hand, if the device 100 is an NMOS device, and NMOS source and drain regions may comprise silicon doped with an appropriate n-type dopant. Thus, in an example, if the device 100 is the PMOS device in which the source and drain regions comprise SiGe, the corresponding regions 141, 151 may comprise silicide, germanide, and/or germanosilicide. In another example, if the device 100 is the NMOS device in which the source and drain regions comprise Si, the corresponding regions 141, 151 may comprise silicide.

Thus, depending on a type of the device 100, the regions 141, 151 may comprise silicide, germanide, and/or germanosilicide. In an example, the silicide, germanide, and/or germanosilicide of the regions 141, 151 comprise one or more metals and one or both of silicon and germanium. For example, the silicide comprises one or more metals and silicon; the germanide comprises one or more metals and germanium; and the germanosilicide comprises one or more metals, silicon, and germanium.

As discussed, the regions 141, 151 comprise one or more metals and one or more semiconductor materials (such as silicon and/or germanium). The one or more metals of the regions 141, 151 comprise one or more of titanium, gadolinium, erbium, scandium, molybdenum, niobium, nickel, cobalt, tungsten, and/or iridium. In an example, if the device 100 is a PMOS, high work function metal may be used for the regions 141, 151. On the other hand, if the device 100 is an NMOS, low work function metal may be used for the regions 141, 151. In an example, if the device 100 is a PMOS device, the metal(s) of the regions 141, 151 may include one or more of titanium, molybdenum, niobium, nickel, cobalt, tungsten, and/or iridium. In another example, if the device 100 is an NMOS device, the metal(s) of the regions 141, 151 may include one or more of titanium, gadolinium, erbium, and/or scandium.

As illustrated in the expanded view of the section 149 in FIG. 1A, dopant 125 and 127 are within the regions 141 and source region 106a. Again, as previously mentioned, various discussion herein below focuses on the source region 106, the source contact 140, and the conductive region 141, and similar discussion also applies to the drain region 106, the drain contact 140, and the conductive region 151 between the drain region 106 and the drain contact 140.

In FIG. 1A, example atoms of the dopant 125 are illustrated using circles with white color inside, and example atoms of the dopant 127 are illustrated using circles with black color inside. In an example, the dopant 125 and the dopant 127 are elementally different. For example, an element within the dopant 125 is not present within the dopant 127, and another element within the dopant 127 is not present within the dopant 125.

As illustrated in FIG. 1A, the dopant 125 is primarily within the source region 106a, and the dopant 127 is primarily within the region 141. For example, a concentration of the dopant 125 within the source region 106a is at least 5%, or 10%, or 15%, or 20%, or 25%, or 30%, or 50%, or 80% more than a concentration of the dopant 125 within the region 141. Similarly, a concentration of the dopant 127 within the region 141 is at least 5%, or 10%, or 15%, or 20%, or 25%, or 30%, or 50%, or 80% more than a concentration of the dopant 127 within the source region 106a. This is symbolically illustrated by showing more white circles (e.g., atoms of dopant 125) within the source region 106a than within the region 141, and by showing more black circles (e.g., atoms of dopant 127) within the region 141 than within the source region 106a. Note that exact locations of the dopant atoms and/or number of the circles illustrating the dopant atoms in FIG. 1A are mere symbolic examples, and are used to primarily convey relative concentration of the dopant in various sections of the device 100.

In an example where the device 100 is a PMOS device, and the dopant 125 (e.g., which is primarily within the source region 106a) comprises a p-type dopant. Examples of p-type dopant 125 within the source region 106a (e.g., when the device 100 is a PMOS) may include boron, gallium, indium, aluminum, and/or another appropriate p-type dopant. The dopant 127 (e.g., which is primarily within the region 141) comprises (i) a p-type dopant, and/or (ii) a dopant that is neither a p-type nor an n-type. Note that in the example of FIG. 1A, the dopant 125 and the dopant 127 are elementally different. So, in an example, if the dopant 125 comprises a p-type dopant such as boron, then the dopant 127 may comprise another p-type of dopant such as gallium, indium, and/or aluminum (but not boron). In another example (still assuming that the device 100 is a PMOS), the dopant 125 may comprise any appropriate p-type dopant, and the dopant 127 may comprise neither a p-type nor an n-type dopant. An example of a dopant that is neither a p-type nor an n-type dopant include carbon. Thus, in this example, the dopant 125 may include boron, gallium, indium, aluminum, and/or another appropriate p-type dopant, while the dopant 127 may include carbon, for example.

In an example where the device 100 is a NMOS device, and the dopant 125 (e.g., which is primarily within the source region 106a) comprises an n-type dopant. Examples of the n-type dopant 125 within the source region 106a (e.g., when the device 100 is an NMOS) may include phosphorous, arsenic, antimony, bismuth, tellurium, and/or another appropriate n-type dopant. The dopant 127 (e.g., which is primarily within the region 141) comprises (i) an n-type dopant and/or (ii) a dopant that is neither a p-type nor an n-type. Note that in the example of FIG. 1A, the dopant 125 and the dopant 127 are elementally different. So, in an example, if the dopant 125 comprise an n-type dopant such as phosphorous, then the dopant 127 may comprise another n-type of dopant such as arsenic, antimony, bismuth, tellurium (but not phosphorous). In another example (still assuming that the device 100 is a NMOS), the dopant 125 may comprise any appropriate n-type dopant, and the dopant 127 may comprise neither a p-type dopant nor an n-type dopant. An example of a dopant that is neither a p-type nor an n-type dopant include carbon. Thus, in this example, the dopant 125 may include phosphorous, arsenic, antimony, bismuth, tellurium, and/or another appropriate n-type dopant, while the dopant 127 may include carbon, for example.

The magnified view of section 149 of FIG. 1A illustrates sections 119a, 119b, 119c of the source region 106. In an example, areas within the section 119a are within a threshold distance d1 from the region 141, areas within the section 119b are between threshold distances d1 and d2 from the region 141, and areas within the section 119c are more than the threshold distance d2 from the region 141. Thus, the section 119a is closer to the region 141 than the section 119b, and the section 119b is closer to the region 141 than the section 119c. In an example, the distance d1 is in the range of 2-15 nanometers (nm), or in the subrange of 2-12 nm, 2-10 nm, 2-8 nm, 2-5 nm, 5-15 nm, or 5-10 nm. In an example, the distance d2 is in the range of 2-15 nanometers (nm), or in the subrange of 2-12 nm, 2-10 nm, 2-8 nm, 2-5 nm, 5-15 nm, or 5-10 nm.

As previously described above, in an example, a concentration of dopant 127 is higher within the region 141 than within the sections 191a, 191b, and 191c of the source region 106. For example, the concentration of the dopant 127 within the region 141 is at least 5%, or 10%, or 15%, or 20%, or 25%, or 30%, or 50%, or 80% more than a concentration of the dopant 127 within any of the sections 119a, 119b, or 119c of source region 106a.

In an example, a concentration of dopant 125 is higher within the source region 106 than within the region 141. For example, the concentration of the dopant 125 within the section 119a and/or within the section 119b is at least 5%, or 10%, or 15%, or 20%, or 25%, or 30%, or 50%, or 80% more than a concentration of the dopant 125 within the region 141.

In an example, a difference between a concentration of dopant 125 within the section 119a and a concentration of dopant 125 within the section 119b is less than 25%, or 20%, or 15%, or 10%, or 5%, or 3%. Thus, in an example, the concentration of dopant 125 within the sections 119a and 119b may be substantially similar (e.g., within 25% of each other). Note that the concentration of the dopant 125 within the section 119c may be less than that in the sections 119a and/or 119b.

In some examples, when the metal for forming the region 141 is deposited, the metal may not include any dopant (e.g., the region 141 in this example will lack dopant 127), while the source region 106 comprises the dopant 125. In some such examples, the region 141 (e.g., silicide, germanide, and/or germanosilicide) doesn't have any dopant initially, and hence, at least some of the dopant 125 migrate or diffuse from the source region (e.g., from at least the section 119a of the source region 106) to the region 141. This at least in part reduces concentration of dopant 125 within the source region 106, e.g., especially within the section 119a immediately adjacent to the region 141. Because of such reduction of concentration of dopant 125 within the section 119a of the source region 106, in an example, contact resistance between the source contact 140 and the source region 106 may increase, thereby adversely impacting performance of the device 100.

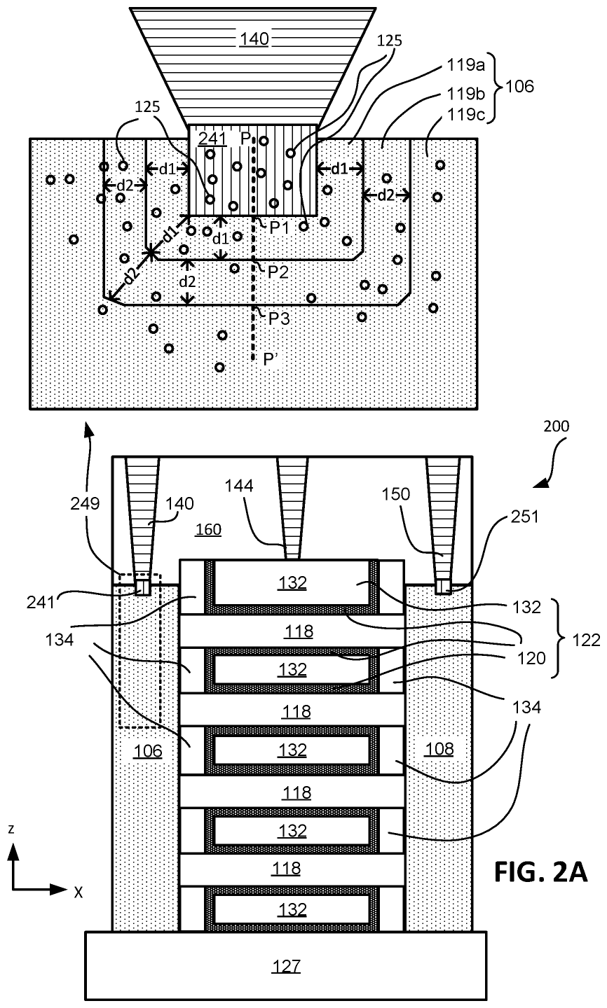

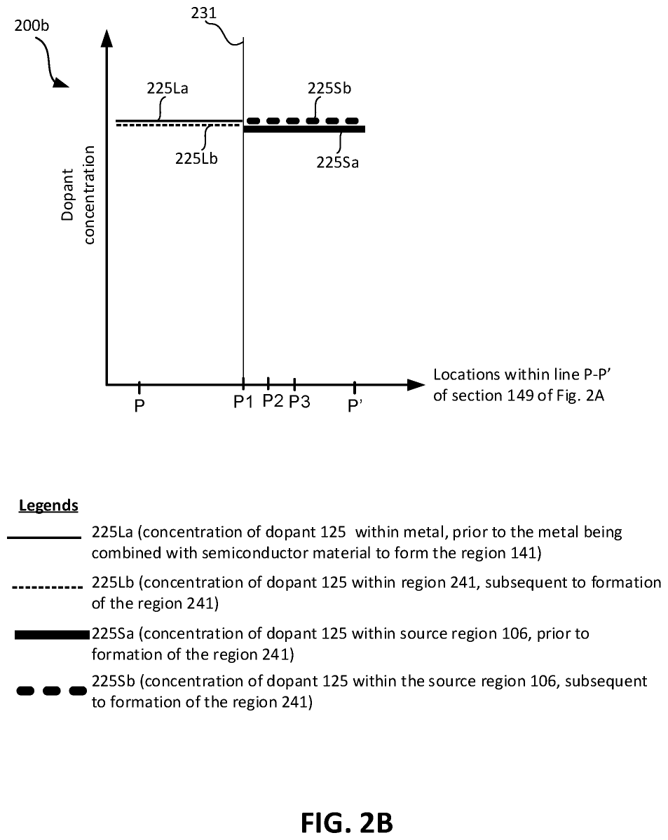

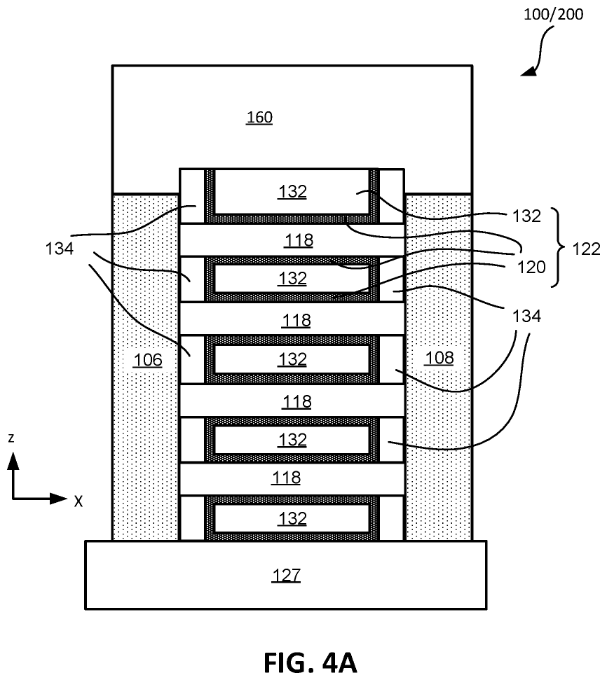

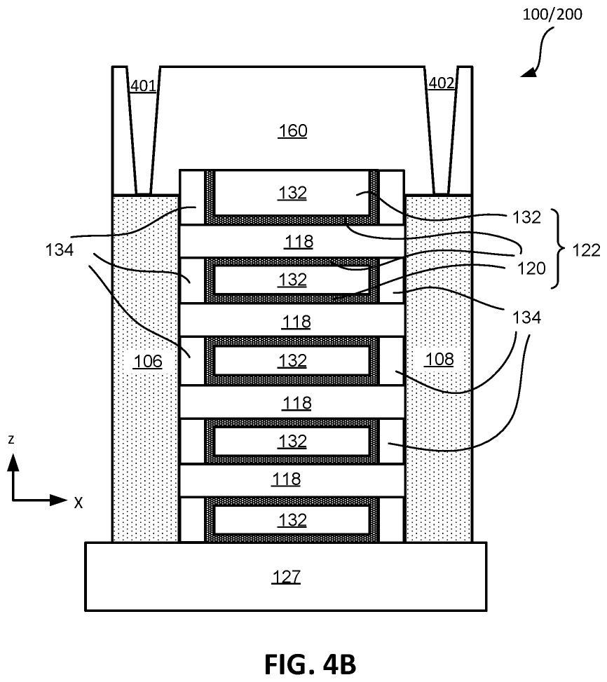

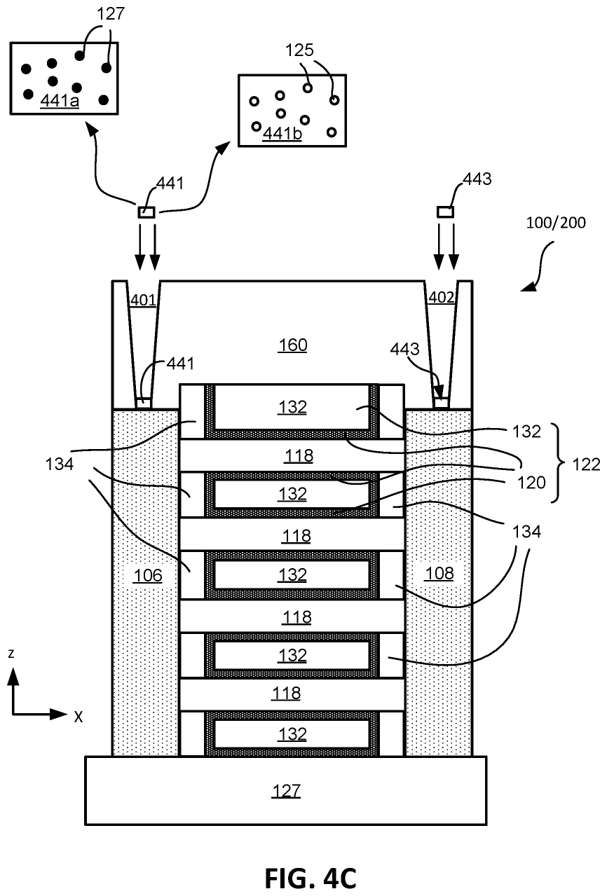

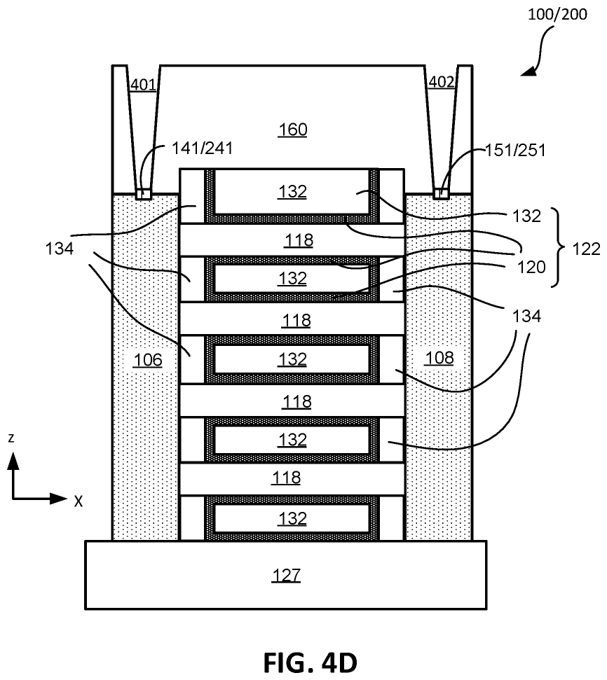

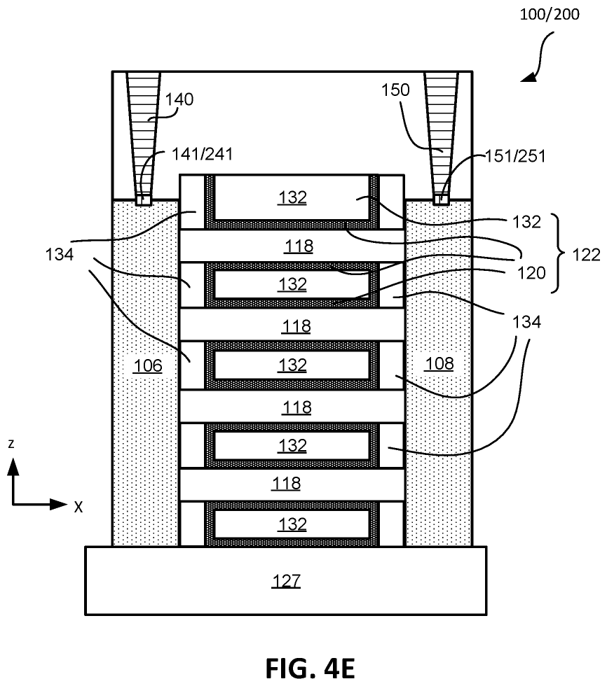

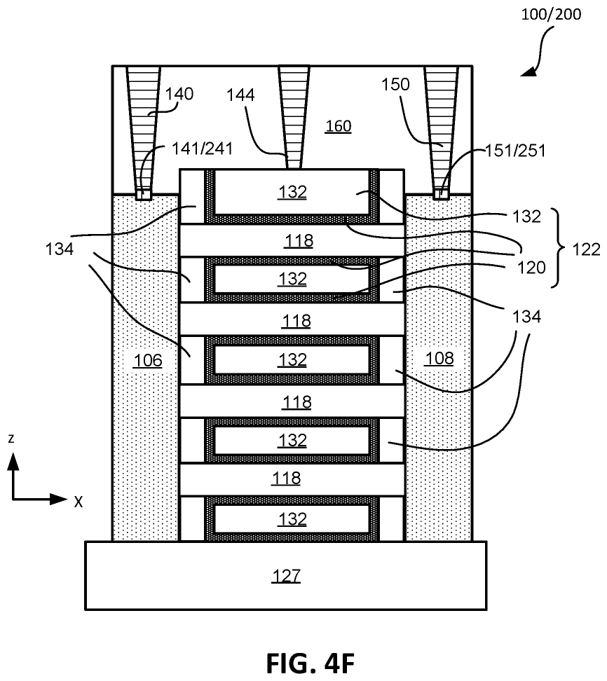

Accordingly, as will be discussed in further detail herein in turn (e.g., with respect to FIGS. 2 and 4C), when the metal for forming the region 141 is deposited within a source trench, the metal comprises (e.g., is pre-doped with) the dopant 127. For example, the metal has about 0.5 to 25% by atomic weight of the dopant 127 doped therewith. Thus, once the region 141 is formed (e.g., when the deposited metal combines with the semiconductor material of the source region 106, e.g., via a high temperature annealing process), the region 141 also includes the dopant 127. Thus, the region 141 is now somewhat saturated with the dopant 127, and cannot accept substantial number of atoms of the dopant 125 from the source region 106. Put differently, substantial diffusion of dopant 125 from the source region 106 to the region 141 is blocked, as the region 141 already includes dopant 127.

For example, some atoms of the dopant 125 may still diffuse from the section 119a of the source region 106 to the region 141, but a number of such diffused atoms of the dopant 125 is much less than the previously discussed example (e.g., where the deposited metal for formation of the region 141 was undoped). Accordingly, the source region 106 (such as the sections 119a, 119b of the source region 106) does not have a substantial reduction in the dopant 125 (e.g., due to substantially less number of atoms of the dopant 125 migrating or diffusing to the region 141), and hence, the previously discussed decrease in concentration of the dopant 125 within the source region 106 (e.g., due to the formation of the region 141) is prevented or at least reduced. Thus, the previously discussed increase in the contact resistance (e.g., due to the formation of the region 141) is eliminated or at least reduced. For example, now the sections 119a, 119b have sufficient concentration of dopant 125, resulting in good (e.g., relatively less) contact resistance between the source contact 140 and the source region 106.

Note that some atoms of the dopant 127 may also diffuse from the region 141 to the source region 106. The diffused atoms of the dopant 127 may, or may not, contribute to maintaining good (e.g., reduced) contact resistance between the source contact 140 and the source region 106, e.g., depending on a type of the dopant 127. For example, for a PMOS device, if the dopant 127 comprise p-type dopant, then the dopant 127 within the source region 106 (e.g., which diffused from the region 141) may contribute in further reduction of the contact resistance between the source contact 140 and the source region 106. Similarly, for an NMOS device, if the dopant 127 comprise an n-type dopant, then the dopant 127 within the source region 106 (e.g., which diffused from the region 141) may contribute in further reduction of the contact resistance between the source contact 140 and the source region 106. However, if the dopant 127 is neither a p-type nor an n-type (e.g., as discussed herein previously), then the dopant 127 within the source region 106 may not substantially contribute in further reduction of the contact resistance between the source contact 140 and the source region 106. However, as the source region 106 (e.g., the sections 119a, 119b) now already has sufficient number of atoms of the dopant 125 (e.g., due to the dopant 127 preventing or reducing diffusion of the dopant 125 from the source region 106 to the region 141), the contact resistance between the source region 106 and the contact 140 may be sufficiently low for satisfactory performance of the device 100.

FIG. 1B illustrates a graph 100b depicting doping concentrations within the source region 106 of FIG. 1A, and within the first region 141 comprising metal and semiconductor material (e.g., silicon and/or germanium) between the source region 106 and the source contact 140 of FIG. 1A, in accordance with an embodiment of the present disclosure. The X-axis of the graph 100b represents locations within a line P-P′ of section 149 of FIG. 1A. Referring to FIGS. 1A and 1B, the point P of the line P-P′ is within the region 141, and the point P′ of the line P-P′ is within the source region 106. A point P1 within the line P-P′ is at a junction between the source region 106 and the region 141. A point P2 within the line P-P′ is at a junction between the sections 191a and 191b of the source region 106. A point P3 within the line P-P′ is at a junction between the sections 191b and 191c of the source region 106. A line 131 within the graph 100b illustrates a segregation between the region 141 and the source region 106 (e.g., left of the line is the region 141, and right of the line is the source region 106). The points P, P1, P2, P3, and P′ are also illustrated along with X-axis of the graph 100b. Also, in FIG. 1B, the Y-axis of the graph 100b represents doping concentrations of the dopants 125, 127 along the line P-P′.

A relative narrow solid line 127a represents concentration of the dopant 127 within metal of region 141, prior to formation of the region 141, e.g., prior to and/or subsequent to the metal being deposited within the source trench for formation of the region 141, but prior to any annealing process that would form the region 141 by combining the metal and the semiconductor material of the source region 106. A relative wide solid line 125a represents concentration of the dopant 125 within the source region 106, prior to formation of the region 141.

A relative narrow dotted line 127b represents concentration of the dopant 127 within the region 141 and the source region 106, subsequent to formation of the region 141. A relative wide dotted line 125b represents concentration of the dopant 125 within the region 141 and the source region 106, subsequent to formation of the region 141. A dashed line 129 represents total or combined concentration of dopants 125 and 127 within the source region 106, subsequent to formation of the region 141.

As illustrated in FIG. 1B, prior to formation of the region 141, the dopant 125 are within the source region 106 (see line 125a) and the dopant 127 are within the metal of the region 141 (see line 127a).

During formation of the region 141, some atoms of the dopant 125 diffuse from the source region 106 to the region 141, and some atoms of the dopant 127 diffuse from the region 141 to the source region 106. Accordingly, there is a slight decline in the concentration of the dopant 125 within the source region 106, as illustrated by line 125b. Similarly, there is a slight decline in the concentration of the dopant 127 within the region 141, as illustrated by line 127b. Thus, the dopant 125 within the section 119a, prior to and subsequent to formation of the region 141, are within 25%, or within 20%, or within 15%, or within 10%, or within 5% of each other. Similarly, the dopant 125 within the section 119b, prior to and subsequent to formation of the region 141, are within 25%, or within 20%, or within 15%, or within 10%, or within 5% of each other. Thus, there is no significant decrease in dopant concentration 125 within the sections 119a and 119b, due to formation of the region 141, thereby preventing or at least reducing effects of formation of the region 141 on dopant concentration within the source region 106.

Note that the line 129 illustrates concentration of combined dopants 125 and 127 within the source region. If the dopant 127 are of p-type (e.g., if the device is a PMOS) or of n-type (e.g., if the device is an NMOS), then the dopant 127 further aid in increasing the appropriate type of dopant within the source region 106, e.g., by increasing the concentration of combined dopant of appropriate type within the source region 106, which further aids in reducing contact resistance.

FIG. 1C illustrates a cross-sectional view of an example FinFET integrated circuit device 100c, where the device 100c comprises (i) a source region 106, a corresponding source contact 140, and a first region 141 comprising metal and semiconductor material between the source region 106 and the source contact 140, (ii) a drain region 108, a corresponding drain contact 150, and a second region 151 comprising metal and semiconductor material between the drain region 108 and the drain contact 150, wherein a first dopant is within the first region 141 and a second dopant is within at least a section of the source region 106, and wherein the first dopant and the second dopant are elementally different, in accordance with an embodiment of the present disclosure. Also, instead of the nanoribbons 118 of FIG. 1A, the device 100c of FIG. 1C includes a fin 118′. Similar components in FIGS. 1A and 1C are labelled similarly. For example, the device 100c of FIG. 1C includes the source region 106, the drain region 108, gate dielectric 120, gate electrode 132, the source contact 140, the drain contact 150, the region 141 between the source region 106 and source contact 140, the region 151 between the drain region 108 and drain contact 150, and the gate contact 144. Discussion with respect to FIG. 1A (e.g., associated with the regions 141, 151, and the source and drain regions 106, 108) also applies to these components of the device 100c of FIG. 1C. Since the cross-section shown here is parallel to the fin and through the channel region, only the top portion of the gate structure can be seen. An orthogonal cross-section will further show the gate structure extending down sides of the fin 118′ as well. Such a configuration is referred to as a tri-gate or FinFET, wherein the gate structure is on top and opposing sides of the fin 118′. A double-gate FinFET is another variation in which the top surface of the fin is not actively gated, such that only the opposing sides of the fin 118′ are gated.

FIG. 2A illustrates a cross-sectional view of an example integrated circuit device 200 (also referred to herein as “device 200”), where the device 200 comprises (i) a source region 106, a corresponding source contact 140, and a first region 241 comprising metal and semiconductor material (e.g., silicon and/or germanium) between the source region 106 and the source contact 140, (ii) a drain region 108, a corresponding drain contact 150, and a second region 151 comprising metal and semiconductor material (e.g., silicon and/or germanium) between the drain region 108 and the drain contact 150, wherein a concentration of a dopant within the first region 141 is within 20% of a concentration of the dopant within a section 119a of the source region 106, where the section 191a of the source region 106 is within a threshold distance d1 from the first region 141, in accordance with an embodiment of the present disclosure.

The device 200 of FIG. 2A is at least in part similar to the device 100 of FIG. 1A, and similar components of the two devices are labelled in the same manner. For example, similar to the device 100 of FIG. 1A, the device 100 FIG. 2A comprises source region 106, drain region 108, source contact 140, drain contact 150, gate stack 122 comprising gate electrode 132 and gate dielectric 120, gate spacer 134, and nanoribbons 118, where the device 200 is formed on a substrate 127.

Similar to the regions 141, 151 of FIG. 1A, the device 200 of FIG. 2A also includes regions 214 and 251, respectively, where the region 241 is between the source contact 140 and the source region 106, and where the region 251 is between the drain contact 150 and the drain region 108, and where the regions 241, 251 comprise silicide, germanide, and/or germanosilicide, e.g., as discussed herein before with respect to regions 141, 151.

However, unlike the regions 141, 151 of the device 100 (e.g., which primarily included the dopant 127 and included some atoms of the dopant 125), the regions 241, 251 of the device 200 of FIG. 2A comprise the dopant 125. Thus, the dopant 127 of FIG. 1A is absent in the device 200 of FIG. 2A, and the regions 241, 251 and the source and drain regions 106, 108 comprise elementally the same dopant 125. Various discussion herein below focuses on the source region 106, the source contact 140, and the conductive region 241, but such discussion also applies to the drain region 106, the drain contact 140, and the conductive region 251 between the drain region 106 and the drain contact 140.

In an example, a concentration of the dopant 125 within the region 241 is within 25%, or 20%, or 15%, or 10%, or 5% of a concentration of the dopant 125 within the section 119a. In an example, a concentration of the dopant 125 within the section 119a is within 25%, or 20%, or 15%, or 10%, or 5% of a concentration of the dopant 125 within the section 119b. Thus, in the device 200, the region 141 and the sections 119a, 119b are substantially uniformly doped with the dopant 125.

In an example where the device 100 is a PMOS device, and the dopant 125 comprise a p-type dopant. Examples of such a p-type dopant 125 within the source region 106a and the region 241 may include boron, gallium, indium, aluminum, and/or another appropriate p-type dopant. In an example where the device 100 is a NMOS device, and the dopant 125 comprise an n-type dopant. Examples of such an n-type dopant 125 within the source region 106a and the region 241 may include phosphorous, arsenic, antimony, bismuth, tellurium, and/or another appropriate n-type dopant.

In some examples, when the metal for forming the region 241 is deposited within the source trench (e.g., see FIGS. 2A and 4C herein in turn), the metal comprises (e.g., is pre-doped with) the dopant 125. Thus, once the region 141 is formed (e.g., when the deposited metal combines with the semiconductor material of the source region 106 during an anneal process), the region 241 also includes the dopant 125. Thus, now both region 241 and the sections 119a, 119b comprise the dopant 125. Thus, the region 241 is now somewhat saturated with the dopant 125, and cannot accept substantial number of additional atoms of the dopant 125 from the source region 106. For example, some dopant 125 atoms may still diffuse from the section 119a to the region 241, and some dopant 125 atoms may also diffuse from the region 141 to the section 119a. But concentration of the dopant 125 within the sections 119a, 119b prior to formation of the region 141 and overall concentration of the dopant 125 within the sections 119a, 119b subsequent to formation of the region 141 are substantially the same (e.g., within 25%, or 20%, or 15%, or 10%, or 5% of each other). Thus, there is no substantial reduction in the dopant concentration due to formation of the region 241. Accordingly, now the sections 119a, 119b have sufficient number of dopant 125 atoms, resulting in good (e.g., relatively less) contact resistance between the source contact 140 and the source region 106.

FIG. 2B illustrates a graph 200b depicting doping concentrations within the source region 106 of FIG. 2A, and within the first region 241 comprising metal and semiconductor material (e.g., silicon and/or germanium) between the source region 106 and the source contact 140 of FIG. 2A, in accordance with an embodiment of the present disclosure. Similar to the graph 100b of FIG. 1B, the X-axis of the graph 200b of FIG. 2B represents locations within a line P-P′ of section 149 of FIG. 2A. Also similar to FIG. 1B, in the graph 200b of FIG. 2B, the Y-axis represents doping concentrations of the dopant 125 along the line P-P′.

A relative narrow solid line 225La represents concentration of the dopant 125 within metal of region 241, prior to formation of the region 241, e.g., prior to and/or subsequent to the metal being deposited within the source trench for formation of the region 241, but prior to any annealing process that would form the region 241 by combining the metal and the semiconductor material of the source region 106. A relative wide solid line 225Sa represents concentration of the dopant 125 within the source region 106, prior to formation of the region 241. A relative narrow dotted line 225Lb represents concentration of the dopant 125 within the region 241, subsequent to formation of the region 241. A relative wide dotted line 225Sb represents concentration of the dopant 125 within the source region 106, subsequent to formation of the region 241.

As illustrated in FIG. 1B, prior to formation of the region 241, the dopant 125 is within the source region 106 (see line 225Sa) and the elementally same dopant 125 is also within the metal of the region 241 (see line 225La).

During formation of the region 241, some atoms of the dopant 125 diffuses from the source region 106 to the region 241, and/or some atoms of the dopant 125 diffuses from the region 241 to the source region 106. Thus, there may be some interchange of atoms of the dopant 125 between the region 241 and the source region 106. Accordingly, there may be some slight change (but not substantially change) in the concentration of the dopant 125 within the source region 106. In the example of FIG. 2B, the dopant concentration within the metal of the region 241 (e.g., prior to formation of the region 241) is slightly higher than the dopant concentration within the source region 106 (e.g., prior to formation of the region 241). Accordingly, there is a net diffusion of dopant atoms from the metal of the region 241 to the source region 106, e.g., during formation of the region 241. Thus, in this example, there is a slight increase in dopant concentration within the source region 106, e.g., after formation of the region 241 (e.g., as line 225Sb is above the line 225Sa).

In an example, although some non-significant change (e.g., change of less than 10% or less than 5%) in dopant concentration may occur in the source region 106 (e.g., where the change may include an increase or decrease of dopant concentration), there is no significant change in dopant concentration within the source region 106 as a result of formation of the region 241. Thus, there is no significant decrease in dopant concentration 125 within the sections 119a and 119b of the source region 106 due to formation of the region 241, thereby preventing or at least reducing effects of formation of the region 241 on dopant concentration within the source region 106. As a result, the formation of the region 241 does not adversely affect the contact resistance of the source contact 140.

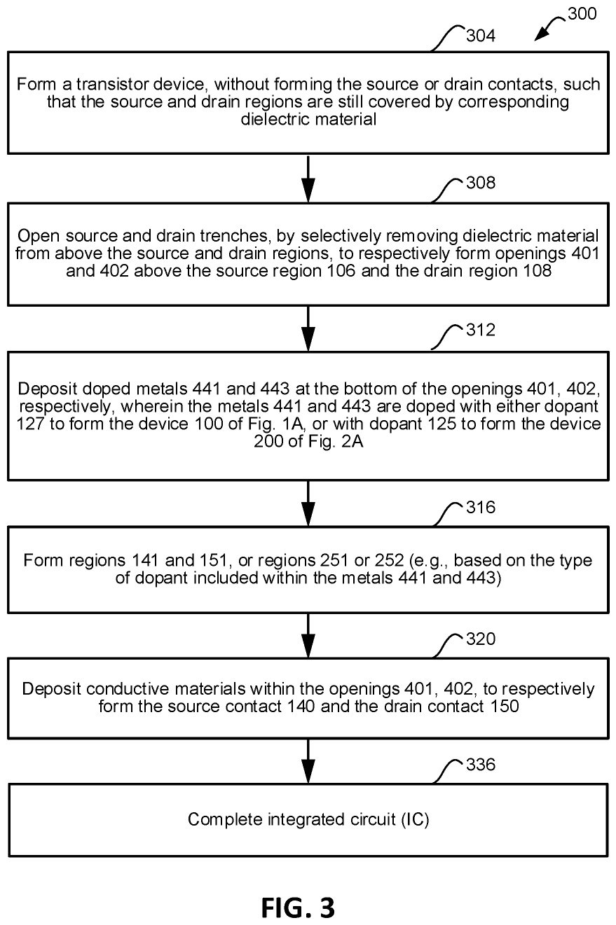

Note that similar to FIG. 1A, the device 200 of FIG. 2A illustrates a GAA device. However, as previously discussed herein, the regions 241, 251 between the source or drain contacts and the corresponding source or drain regions can be within any appropriate type of transistor devices, such as the FinFET device 100c illustrated in FIG. 1C. Another example transistor configuration that can benefit from the techniques described herein is the forksheet transistor. In a forksheet transistor, the channel region includes one or more nanosheets or fin-like structures extending laterally from a dielectric spine. The gate structure is on three sides of the one or more nanosheets or fin-like structures, and source and drain regions can be formed adjacent the channel region. Any suitable processing can be used to form the fork sheet transistor structure. In any such case, contacts can be formed on the source and drain regions using the methodology of FIG. 3, in accordance with an embodiment. The techniques described herein can also be readily applied to planar transistor structures. Again, any suitable processing can be used to form the planar transistor structure. In any such case, contacts can be formed on the source and drain regions using the methodology of FIG. 3, in accordance with an embodiment. More generally, any number of transistor structures that can benefit from low-resistance contacts can be formed using the techniques described herein.

FIG. 3 illustrates a flowchart depicting a method 300 of forming any of the example integrated circuit device 100 or 200 of FIG. 1A or 1B, in accordance with an embodiment of the present disclosure. FIGS. 4A, 4B, 4C, 4D, 4E, and 4F collectively illustrate cross-sectional views of an example integrated circuit device semiconductor structure (e.g., the integrated circuit device 100 or 200 of FIG. 1A or 2A) in various stages of processing, in accordance with an embodiment of the present disclosure. FIGS. 3 and 4A-4F will be discussed in unison. The cross-sectional views of FIGS. 4A-4F correspond to the cross-sectional views of FIGS. 1A and 1B.

As discussed, the method 200 can be used to form either of the devices 100 or 200 of FIG. 1A or 1B. Accordingly, in FIGS. 4A-4F where formation of the device is illustrated, the device is labelled as and referred to as device 100/200.

Referring to FIG. 3, the method 300 includes, at 304, forming a transistor device (e.g., device 100 or 200 of FIG. 1A or 1B, respectively), without forming the source or drain contacts of the device. After process 304, an example of the resulting device 100/200 is shown in FIG. 4A. Note that in FIG. 4A, a nanoribbon transistor is illustrated, however the transistor device of process 304 can be any appropriate transistor device in which a source contact and a drain contact is yet to be formed. The formation process 304 can be performed with appropriate techniques for forming transistor devices. As discussed, the source and drain contacts have not been formed yet and source and drain trenches have not been opened yet, and the source and drain regions are covered by dielectric material 160. Note that after process 204, the source and drain regions have been appropriately doped with the dopant 125, e.g., as discussed herein previously with respect to FIGS. 1A and 2A.

Referring again to FIG. 3, the method 300 proceeds from 304 to 308, where source and drain trenches are opened, by selectively removing dielectric material 160 from above the source region 106 and the drain region 108, to respectively form openings 401 and 402 above the source region 106 and the drain region 108, e.g., as illustrated in FIG. 4B. The dielectric material 160 is selectively removed from above the source and drain regions 106, 108, e.g., using appropriate etching techniques.

Referring again to FIG. 3, the method 300 proceeds from 308 to 312, where doped metals 441 and 443 are respectively deposited at the bottom of the openings 401, 402, e.g., as illustrated in FIG. 4C. In an example, the metals 441 and 443 are doped with either the dopant 127 to form the device 100 of FIG. 1A, or with the dopant 125 to form the device 200 of FIG. 2A. For example, FIG. 4C illustrates the metal 441 being doped with either dopant 125 or 127. Examples of the metals 441, 443 and dopant 125 and 127 have been discussed herein previously. In an example, the metals 441, 443 are deposited using an appropriate deposition technique, such as chemical vapor deposition (CVD), physical vapor deposition (PVD), atomic layer deposition (ALD), vapor-phase epitaxy (VPE), molecular beam epitaxy (MBE), liquid-phase epitaxy (LPE), or sputtering, for example.

In one example, the deposition process receives substantially undoped metal from a first source and the dopant from a second source, the simultaneously deposits the metal and the dopant with the openings 401, 402. In another example, the deposition process receives doped metal, the deposits the doped metal with the openings 401, 402.

Referring again to FIG. 3, the method 300 proceeds from 312 to 316, where regions 141 and 151, or regions 251 or 252 are formed, as illustrated in FIG. 4D. For example, either regions 141 and 151, or regions 241 and 215 are formed, based on the type of dopant included within the metals 441 and 443. Inclusion of the dopant 127 within the metals 441, 443 results in formation of the regions 141 and 151, as discussed with respect to FIG. 1A. On the other hand, inclusion of the dopant 125 within the metals 441, 443 results in formation of the regions 241 and 251, as discussed with respect to FIG. 2A. As illustrated in FIG. 4D, regions 141 or 241 (referred to herein as 141/241) are formed above the source region 106, at the bottom of the opening 401. Similarly, regions 151 or 251 (referred to herein as 151/251) are formed above the drain region 108, at the bottom of the opening 402. In an example, the process 316 includes annealing the metals 441, 443 and adjacent source or drain regions, resulting in formation of the regions 141/151 or 241/251. For example, the metals 441, 443 combines with the semiconductor materials of the source or drain regions 106, 108 (e.g., during the high temperature anneal process), to form the silicide, germanide, and/or germanosilicide of these regions.

Referring again to FIG. 3, the method 300 proceeds from 316 to 320, where conductive materials are deposited within the openings 401, 402, to respectively form the source contact 140 and the drain contact 150, as illustrated in FIG. 4E. Note that the conductive materials can be multilayer materials, such as materials for one or more liner or barrier layers (e.g., to prevent diffusion of the conductive material to adjacent dielectric material 160), adhesive layers, and/or conductive fill material to fill the openings 401, 402.

Referring again to FIG. 3, the method 300 proceeds from 320 to 324, where a general integrated circuit (IC) is completed, as desired, in accordance with some embodiments. Such additional processing to complete an IC may include forming gate contact 144 (see FIG. 4F, for example), back-end or back-end-of-line (BEOL) processing to form one or more frontside and/or backside metallization layers (e.g., such as a frontside logic interconnect structure and/or a backside power delivery network structure). Any other suitable processing may be performed, as will be apparent in light of this disclosure.

Note that the processes in method 300 are shown in a particular order for ease of description. However, one or more of the processes may be performed in a different order or may not be performed at all (and thus be optional), in accordance with some embodiments. Numerous variations on method 300 and the techniques described herein will be apparent in light of this disclosure.

### Example System

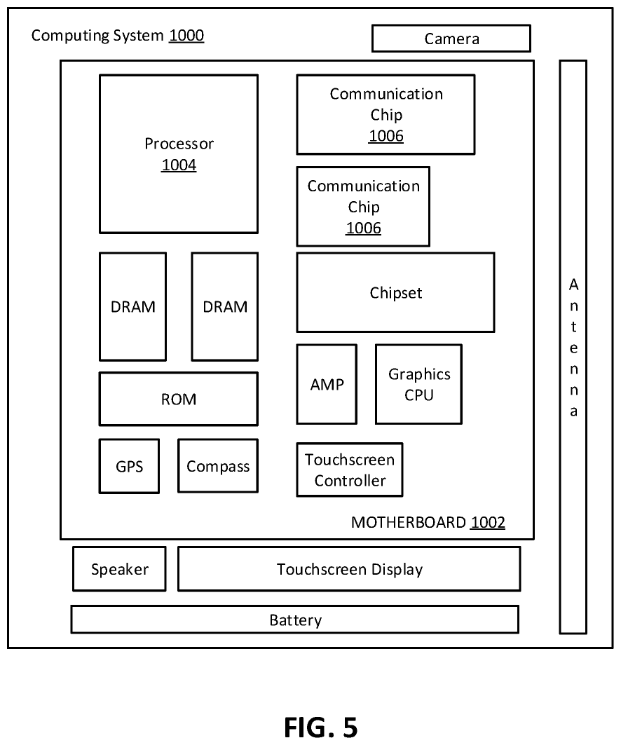

FIG. 5 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### Further Example Embodiments

The following clauses pertain to further embodiments, from which numerous permutations and configurations will be apparent.

Example 1. An integrated circuit structure, comprising: a source or drain region; a contact comprising conductive material; a region between at least a section of the source or drain region and the contact, the region comprising a metal and one or more semiconductor materials; and a first dopant within the source or drain region, and a second dopant within the region between the at least a section of the source or drain region and the contact, the first dopant elementally different from the second dopant.

Example 2. The integrated circuit structure of example 1, wherein the region between the at least a section of the source or drain region and the contact comprises one or more of silicide, germanide, and/or germanosilicide of the one or more metals.

Example 3. The integrated circuit structure of any one of examples 1-2, wherein: the first dopant is also within the region between the at least a section of the source or drain region and the contact, wherein a concentration of the first dopant within the region between the at least a section of the source or drain region and the contact is less than a concentration of the first dopant within the source or drain region.

Example 4. The integrated circuit structure of any one of examples 1-2, wherein: the first dopant is also within the region between the at least a section of the source or drain region and the contact, wherein a concentration of the first dopant within the region between the at least a section of the source or drain region and the contact is less than a concentration of the first dopant within at least a portion of the source or drain region, the portion of the source or drain region at a distance of at most 5 nanometers (nm) from the region between the at least a section of the source or drain region and the contact.

Example 5. The integrated circuit structure of any one of examples 1-4, wherein: the second dopant is also within the source or drain region, wherein a concentration of the second dopant within the source or drain region is less than a concentration of the second dopant within the region between the at least a section of the source or drain region and the contact.

Example 6. The integrated circuit structure of any one of examples 1-5, wherein each of the first dopant and the second dopant comprises a p-type dopant.

Example 7. The integrated circuit structure of any one of examples 1-5, wherein the first dopant comprises a p-type dopant, and the second dopant comprises neither a p-type dopant nor an n-type dopant.

Example 8. The integrated circuit structure of any one of examples 1-5, wherein the first dopant comprises boron, and the second dopant comprises one or more of gallium, indium, aluminum, or carbon.

Example 9. The integrated circuit structure of any one of examples 1-5, wherein each of the first dopant and the second dopant comprises an n-type dopant.

Example 10. The integrated circuit structure of any one of examples 1-5, wherein the first dopant comprises an n-type dopant, and the second dopant comprises neither a p-type dopant nor an n-type dopant.

Example 11. The integrated circuit structure of any one of examples 1-5, wherein the first dopant comprises phosphorous, and the second dopant comprises one or more of arsenic, antimony, bismuth, tellurium, or carbon.

Example 12. The integrated circuit structure of any one of examples 1-11, wherein the one or more metals comprise one or more of titanium, gadolinium, erbium, scandium, molybdenum, niobium, nickel, cobalt, tungsten, or iridium.

Example 13. The integrated circuit structure of any one of examples 1-12, wherein the one or more semiconductor materials comprise one or both of silicon and germanium.

Example 14. The integrated circuit structure of any one of examples 1-13, wherein the source or drain region is a first source or drain region, the contact is a first contact, the region is a first region, and wherein the integrated circuit structure further comprises: a second source or drain region; a body comprising semiconductor material extending from the first source or drain region to the second source or drain region; a second contact coupled to the second source or drain region; and a second region comprising one or more additional metals and the one or more semiconductor materials, the second region between at least a section of the second source or drain region and the second contact, wherein the second source or drain region comprises the first dopant, and the second region comprises the second dopant.

Example 15. An integrated circuit structure, comprising: a source or drain region; a contact coupled to the source or drain region; a region comprising one or more of silicide, germanide, and/or germanosilicide, the region between the source or drain region and the contact, wherein a portion of the source or drain region is at a distance that is at most 5 nanometers (nm) from the region comprising the one or more of silicide, germanide, and/or germanosilicide; and a dopant within the region and within the source or drain region, wherein a concentration of the dopant within the region is within 20% of a concentration of the dopant within the portion of the source or drain region.

Example 16. The integrated circuit structure of example 15, wherein the concentration of the dopant within the region is within 10% of the concentration of the dopant within the portion of the source or drain region.

Example 17. The integrated circuit structure of any one of examples 15-16, wherein the portion is a first portion, wherein a second portion of the source or drain is between 5 to 10 nm of the region, and wherein the concentration of the dopant within the region is within 20% of a concentration of the dopant within the second portion of the source or drain region.

Example 18. The integrated circuit structure of any one of examples 15-17, wherein the integrated circuit structure is a p-channel metal-oxide-semiconductor (PMOS) device, and the dopant comprises one or more of boron, gallium, indium, or aluminum.

Example 19. The integrated circuit structure of any one of examples 15-17, wherein the integrated circuit structure is a n-channel metal-oxide-semiconductor (NMOS) device, and the dopant comprises one or more of phosphorous, arsenic, antimony, bismuth, or tellurium.

Example 20. A method for forming silicide, germanide, and/or germanosilicide adjacent to a source or drain region, the method comprising: forming the source or drain region, the source or drain region covered by dielectric material; forming a recess within the dielectric material, the recess landing on the source or drain region; depositing metal within a bottom section of the recess and adjacent to the source or drain region, wherein the deposited metal is doped with one or more dopants prior to the deposition; and processing the metal and the source or drain region, to form the silicide, germanide, and/or germanosilicide adjacent to the source or drain region.

Example 21. The method of example 20, further comprising: forming a contact, such that the silicide, germanide, and/or germanosilicide is between the source or drain region and the contact.

Example 22. The method of any one of examples 20-21, wherein the one or more dopants within the metal are first one or more dopants, and the method further comprises: prior to forming the recess, doping at least a section of the source or drain region with second one or more dopants.

Example 23. The method of example 22, wherein the first one or more dopants are elementally different from the second one or more dopants.

Example 24. The method of any one of examples 22-23, wherein: the source or drain region is a p-type source or drain region, the second one or more dopants are p-type dopants, and the first one or more dopants are either (i) one or more p-type dopants, or (ii) neither p-type nor n-type dopants.

Example 25. The method of any one of examples 22-23, wherein: the source or drain region is a n-type source or drain region, the second one or more dopants are n-type dopants, and the first one or more dopants are either (i) n-type dopants, or (ii) neither p-type nor n-type dopants.

Example 26. The method of any one of examples 20-25, wherein processing the metal and the source or drain region comprises: annealing the metal and the source or drain region, to form the silicide, germanide, and/or germanosilicide.

Example 27. The method of any one of examples 20-26, wherein prior to depositing the metal, the metal to be deposited is doped with one or more of boron, gallium, indium, aluminum, or carbon.

Example 28. The method of any one of examples 20-26, wherein prior to depositing the metal, the metal to be deposited is doped with one or more of phosphorous, arsenic, antimony, bismuth, tellurium, or carbon.

Example 29. The method of any one of examples 20-28, wherein a concentration of the one or more dopants within the metal to be deposited is in the range of 1-20% by atomic weight.

Example 30. The method of any one of examples 20-26, wherein the source or drain region comprises an n-type dopant, and the metal comprises one or more of titanium, gadolinium, erbium, scandium.

Example 31. The method of any one of examples 20-26, wherein the source or drain region comprises a p-type dopant, and the metal comprises one or more of titanium, molybdenum, niobium, nickel, cobalt, tungsten, or iridium.

Example 32. The method of any one of examples 20-31, wherein depositing the metal comprises depositing the metal using a sputtering process.

The foregoing description of example embodiments has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto. Future filed applications claiming priority to this application may claim the disclosed subject matter in a different manner, and may generally include any set of one or more limitations as variously disclosed or otherwise demonstrated herein.

What is claimed is:

1. An integrated circuit structure, comprising:
a source or drain region;
a contact comprising conductive material;
a region between at least a section of the source or drain region and the contact, the region comprising a metal and one or more semiconductor materials; and
a first dopant within the source or drain region, and a second dopant within the region between the at least a section of the source or drain region and the contact, the first dopant elementally different from the second dopant.

2. The integrated circuit structure of claim 1, wherein the region between the at least a section of the source or drain region and the contact comprises one or more of silicide, germanide, and/or germanosilicide of the one or more metals.

3. The integrated circuit structure of claim 1, wherein:
the first dopant is also within the region between the at least a section of the source or drain region and the contact, wherein a concentration of the first dopant within the region between the at least a section of the source or drain region and the contact is less than a concentration of the first dopant within the source or drain region.

4. The integrated circuit structure of claim 1, wherein:
the first dopant is also within the region between the at least a section of the source or drain region and the contact, wherein a concentration of the first dopant within the region between the at least a section of the source or drain region and the contact is less than a concentration of the first dopant within at least a portion of the source or drain region, the portion of the source or drain region at a distance of at most 5 nanometers (nm) from the region between the at least a section of the source or drain region and the contact.

5. The integrated circuit structure of claim 1, wherein:
the second dopant is also within the source or drain region, wherein a concentration of the second dopant within the source or drain region is less than a concentration of the second dopant within the region between the at least a section of the source or drain region and the contact.

6. The integrated circuit structure of claim 1, wherein each of the first dopant and the second dopant comprises a p-type dopant.

7. The integrated circuit structure of claim 1, wherein the first dopant comprises a p-type dopant, and the second dopant comprises neither a p-type dopant nor an n-type dopant.

8. The integrated circuit structure of claim 1, wherein the first dopant comprises boron, and the second dopant comprises one or more of gallium, indium, aluminum, or carbon.

9. The integrated circuit structure of claim 1, wherein each of the first dopant and the second dopant comprises an n-type dopant.

10. The integrated circuit structure of claim 1, wherein the first dopant comprises an n-type dopant, and the second dopant comprises neither a p-type dopant nor an n-type dopant.

11. The integrated circuit structure of claim 1, wherein the first dopant comprises phosphorous, and the second dopant comprises one or more of arsenic, antimony, bismuth, tellurium, or carbon.

12. The integrated circuit structure of claim 1, wherein the one or more metals comprise one or more of titanium, gadolinium, erbium, scandium, molybdenum, niobium, nickel, cobalt, tungsten, or iridium.

13. The integrated circuit structure of claim 1, wherein the source or drain region is a first source or drain region, the contact is a first contact, the region is a first region, and wherein the integrated circuit structure further comprises:
a second source or drain region;
a body comprising semiconductor material extending from the first source or drain region to the second source or drain region;
a second contact coupled to the second source or drain region; and
a second region comprising one or more additional metals and the one or more semiconductor materials, the second region between at least a section of the second source or drain region and the second contact,
wherein the second source or drain region comprises the first dopant, and the second region comprises the second dopant.

14. An integrated circuit structure, comprising:
a source or drain region;
a contact coupled to the source or drain region;
a region comprising one or more of silicide, germanide, and/or germanosilicide, the region between the source or drain region and the contact, wherein a portion of the source or drain region is at a distance that is at most 5 nanometers (nm) from the region comprising the one or more of silicide, germanide, and/or germanosilicide; and
a dopant within the region and within the source or drain region, wherein a concentration of the dopant within the region is within 20% of a concentration of the dopant within the portion of the source or drain region.

15. The integrated circuit structure of claim 14, wherein the concentration of the dopant within the region is within 10% of the concentration of the dopant within the portion of the source or drain region.

16. The integrated circuit structure of claim 14, wherein the portion is a first portion, wherein a second portion of the source or drain is between 5 to 10 nm of the region, and wherein the concentration of the dopant within the region is within 20% of a concentration of the dopant within the second portion of the source or drain region.

17. A method for forming silicide, germanide, and/or germanosilicide adjacent to a source or drain region, the method comprising:
forming the source or drain region, the source or drain region covered by dielectric material;
forming a recess within the dielectric material, the recess landing on the source or drain region;
depositing metal within a bottom section of the recess and adjacent to the source or drain region, wherein the metal to be deposited is doped with one or more dopants prior to the deposition; and
processing the metal and the source or drain region, to form the silicide, germanide, and/or germanosilicide adjacent to the source or drain region.

18. The method of claim 17, further comprising:
forming a contact, such that the silicide, germanide, and/or germanosilicide is between the source or drain region and the contact.

19. The method of claim 17, wherein the one or more dopants within the metal are first one or more dopants, and the method further comprises:
prior to forming the recess, doping at least a section of the source or drain region with second one or more dopants.

20. The method of claim 17, wherein prior to depositing the metal, the metal to be deposited is doped with one or more of boron, gallium, indium, aluminum, or carbon.

21. The method of claim 17, wherein prior to depositing the metal, the metal to be deposited is doped with one or more of phosphorous, arsenic, antimony, bismuth, tellurium, or carbon.

22. The method of claim 17, wherein a concentration of the one or more dopants within the metal to be deposited is in the range of 1-20% by atomic weight.

23. The method of claim 17, wherein the source or drain region comprises an n-type dopant, and the metal comprises one or more of titanium, gadolinium, erbium, scandium.

24. The method of claim 17, wherein the source or drain region comprises a p-type dopant, and the metal comprises one or more of titanium, molybdenum, niobium, nickel, cobalt, tungsten, or iridium.

25. The method of claim 17, wherein depositing the metal comprises depositing the metal using a sputtering process.
